(19) United States
(12) Patent Application Publication
(10) Pub. No.: US 2025/0359386 A1
(43) Pub. Date: Nov. 20, 2025

(54) Hybrid Image Sensor with Both Split Photodetection and Square Photodetection Pixels

(71) Applicant: Apple Inc., Cupertino, CA (US)

(72) Inventor: Jiaju Ma, Arcadia, CA (US)

(73) Assignee: Apple Inc., Cupertino, CA (US)

(21) Appl. No.: 19/059,117

(22) Filed: Feb. 20, 2025

Related U.S. Application Data
(60) Provisional application No. 63/649,856, filed on May 20, 2024.

(51) Int. Cl. H10F 39/00; H04N 25/78

(52) U.S. Cl. CPC H10F 39/813; H04N 25/78; H10F 39/8023; H10F 39/8053; H10F 39/8057; H10F 39/8063; H10F 39/809

(57) ABSTRACT

Various structures for a hybrid pixel array are disclosed. The hybrid pixel array includes a combination of square photodiode (PD) pixel structures and split PD pixel structures. Square PD pixel structures include one photodiode per pixel unit while split PD pixel structures include two photodiodes per pixel unit. In certain instances, square PD pixel structures are used for green light pixels and split PD pixel structures are used for blue and red light pixels in the hybrid pixel array. The combination of square PD pixel structures and split PD pixel structures provides autofocus capability with higher signal strengths. Various techniques for row addressing and readout from the hybrid pixel array are also disclosed.

### CROSS REFERENCE TO RELATED APPLICATIONS

The present application claims priority to U.S. Provisional App. No. 63/649,856, entitled “Hybrid Image Sensor with Both Split Photodetection and Square Photodetection Pixels,” filed May 20, 2024, the disclosure of which is incorporated by reference herein in its entirety.

### BACKGROUND

### Technical Field

This disclosure relates generally to an image sensor and more specifically to designs of pixels for capturing light on an image sensor with hybrid pixel photodetection capabilities.

### Description of the Related Art

Image capturing devices, such as cameras, are widely used in various electronic devices, such as mobile devices (e.g., smart phones, tablets, laptops, etc.), robotic equipment, or security monitoring devices, among others. An image capturing device may include an image sensor having a plurality of light-gathering pixels. A pixel may include a photodiode. The image capturing device may capture light from an environment and pass the light to the image sensor. When exposed to light, the photodiodes of the pixels may accumulate photoelectrons. Digital images may produced from an array of pixels by reading out analog signals (e.g., voltage signals) from the pixels and converting the analog signals to digital signals that are then processed by image signal processors to generate a digital image. There are various types of pixel structures that may be implemented in pixel arrays. Pixel arrays typically include all the same pixel structures across the array for simplicity in processing and programming (e.g., addressing and readout) of the pixel array. While having all the same pixel structures across the pixel array may simplify processing and programming, performance trade-offs may be made between using different types of pixel structures in pixel arrays.

### BRIEF DESCRIPTION OF THE DRAWINGS

FIG. 1 is a top plan view of an example pixel array having square PD pixel structures, according to some embodiments.

FIG. 2 is an example schematic diagram for a portion of a pixel array, according to some embodiments.

FIG. 3 is a top plan view of an example pixel array having split PD pixel structures, according to some embodiments.

FIG. 4 is an example schematic diagram for a portion of a pixel array, according to some embodiments.

FIG. 5 is a top plan view of a contemplated hybrid pixel array, according to some embodiments.

FIG. 6 is an example schematic diagram for a portion of a pixel array, according to some embodiments.

FIG. 7 is a top plan view of another contemplated hybrid pixel array, according to some embodiments.

FIG. 8 is an example schematic diagram for a portion of a pixel array, according to some embodiments.

FIG. 9 is a circuit layout for addressing and readout of a pixel array, according to some embodiments.

FIG. 10 depicts a timing diagram for operation of transistors in pixel arrays, according to some embodiments.

FIG. 11 is a top plan view of yet another contemplated hybrid pixel array, according to some embodiments.

FIG. 12 is an example process flow for forming a hybrid pixel array structure, according to some embodiments.

FIG. 13 is a schematic diagram of an example image sensor, according to some embodiments.

FIG. 14 is a flowchart showing an example method for processing image signals of an image sensor to generate a digital image, according to some embodiments.

FIG. 15 illustrates a schematic representation of an example device that may include an image capturing device (e.g., a camera) having an image sensor, according to some embodiments.

FIG. 16 illustrates a schematic block diagram of an example computing device that may include or host embodiments of an image capturing device (e.g., a camera) having an image sensor, according to some embodiments.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

“Comprising.” This term is open-ended. As used in the appended claims, this term does not foreclose additional structure or steps. Consider a claim that recites: “An apparatus comprising one or more processor units . . . .” Such a claim does not foreclose the apparatus from including additional components (e.g., a network interface unit, graphics circuitry, etc.).

“Configured To.” Various units, circuits, or other components may be described or claimed as “configured to” perform a task or tasks. In such contexts, “configured to” is used to connote structure by indicating that the units/circuits/components include structure (e.g., circuitry) that performs those task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. § 112(f) for that unit/circuit/component. Additionally, “configured to” can include generic structure (e.g., generic circuitry) that is manipulated by software and/or firmware (e.g., an FPGA or a general-purpose processor executing software) to operate in manner that is capable of performing the task(s) at issue. “Configure to” may also include adapting a manufacturing process (e.g., a semiconductor fabrication facility) to fabricate devices (e.g., integrated circuits) that are adapted to implement or perform one or more tasks.

“First,” “Second,” etc. As used herein, these terms are used as labels for nouns that they precede, and do not imply any type of ordering (e.g., spatial, temporal, logical, etc.). For example, a buffer circuit may be described herein as performing write operations for “first” and “second” values. The terms “first” and “second” do not necessarily imply that the first value must be written before the second value.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

It will also be understood that, although the terms first, second, etc. may be used herein to describe various elements, these elements should not be limited by these terms. These terms are only used to distinguish one element from another. For example, a first contact could be termed a second contact, and, similarly, a second contact could be termed a first contact, without departing from the intended scope. The first contact and the second contact are both contacts, but they are not the same contact.

The terminology used in the description herein is for the purpose of describing particular embodiments only and is not intended to be limiting. As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

### DETAILED DESCRIPTION

Various embodiments described herein relate to image sensors with combinations of different types of pixel structures. In certain embodiments, the image sensors include pixel arrays that have a combination of square photodiode (PD) pixel structures and split photodiode (PD) pixel structures. Square PD pixel structures are pixel structures that have one photodiode per pixel structure unit. Split PD pixel structures are pixel structures that have two photodiodes per pixel structure unit. Split PD pixel structures typically have rectangular shaped photodiodes each occupying half of the area of the pixel structure unit. Image sensors with both square PD pixel structures and split PD pixel structures may take advantage of the benefits of both types of pixel structures while reducing the trade-offs associated with having only one type of pixel structure on the image sensor.

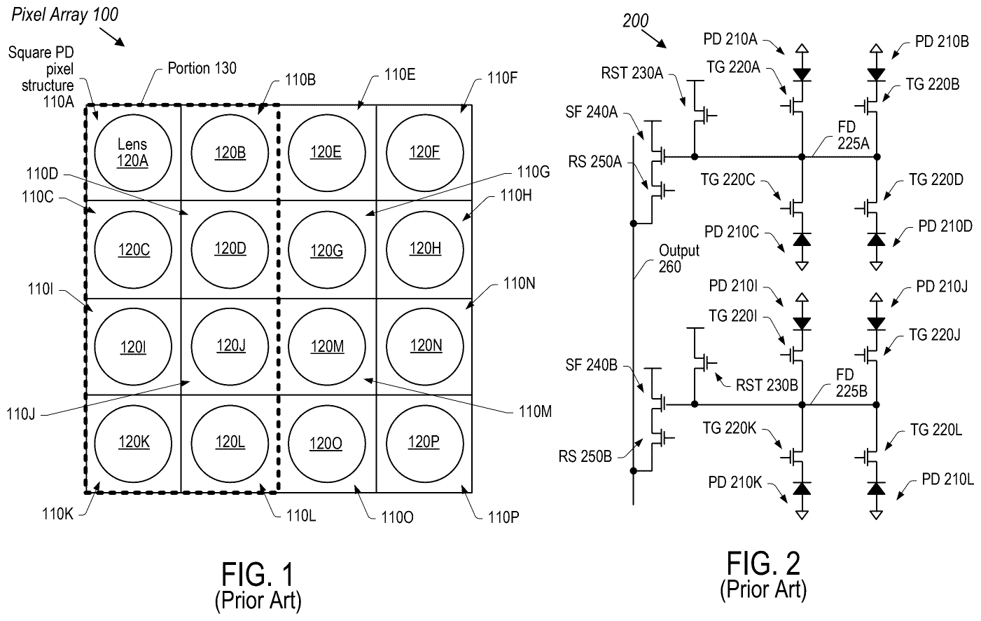

FIG. 1 is a top plan view of an example pixel array having square PD pixel structures, according to some embodiments. In the illustrated embodiment, pixel array 100 includes square PD pixel structures 110A-P. For square PD pixel structures 110, each square PD pixel structure 110 has one photodiode (not shown) inside its square-shaped perimeter. Thus, pixel array 100 has one photodiode per square-shaped unit (square-shaped units being defined by the perimeter shape of pixel structures 110). Additionally, each square PD pixel structure 110A-P includes a corresponding lens 120A-P in pixel array 100. Lens 120 may be, for example, a micro-lens or other lens structure for focusing light onto the photodiode in square PD pixel structure 110.

In some embodiments, pixel array 100 is a color filter array having a combination of red (R) pixel structures, green (G) pixel structures, and blue (B) pixel structures (e.g., the color filter array is an RGB filter array). Red pixel structures includes photodiodes that accumulate photoelectrons when exposed to red light (e.g., light at red light spectrum wavelengths). Green pixel structures includes photodiodes that accumulate photoelectrons when exposed to green light (e.g., light at green light spectrum wavelengths). Blue pixel structures includes photodiodes that accumulate photoelectrons when exposed to blue light (e.g., light at blue light spectrum wavelengths).

In various embodiments, pixel array 100 may include larger numbers of green pixel structures to correspond to operation of a human eye in collecting light for generating images since human eyes have a more attuned (e.g., heightened) sensitivity to green light spectrum wavelengths. Additionally, in some lighting conditions (such as outdoors or well-lit indoor areas), green light spectrum wavelengths may have a stronger intensity compared to red or blue light spectrum wavelengths. Thus, having larger numbers of green pixel structures may increase image quality for images generated by the image sensor having pixel array 100.

In the illustrated embodiment of FIG. 1, pixel structures 110A-D and 110M-P are green pixel structures, pixel structures 110E-H are blue pixel structures, and pixel structures 110I-L are red pixel structures. Thus, pixel array 100 includes 8 green pixel structures, 4 blue pixel structures, and 4 red pixel structures. It should be understood, however, that any number or combination of different color pixel structures may be implemented in pixel array 100. Additionally, as pixel array 100 includes square PD pixel structures 110A-P, the pixel array does not have any phase detection auto-focus (PDAF) capability. PDAF capability may be implemented for pixel array 100 by the addition of optical shielding (described herein) or multi-pixel on-chip lens (OCL) to one or more pixel structures 110 in the pixel array.

FIG. 2 is an example schematic diagram for a portion of pixel array 100, according to some embodiments. In the illustrated embodiment, schematic diagram 200 is provided for portion 130 of pixel array 100 (shown by the dashed lines in FIG. 1). Portion 130, as shown in FIG. 1, includes pixel structures 110A-D and pixel structures 110I-L. As shown in FIG. 2, schematic diagram 200 includes photodiodes (PD) 210A-D and photodiodes (PD) 210I-L, which correspond to pixel structures 110A-D and pixel structures 110I-L from FIG. 1, respectively. Each PD 210A-D and PD 210I-L has its own corresponding transfer gate (TG) 220A-D and TG 220I-L, respectively.

TG 220A-D are coupled together at floating diffusion (FD) region 225A while TG 220I-L are coupled together at floating diffusion (FD) region 225B. FD region 225A is coupled to reset gate (RST) 230A, source follower (SF) transistor 240A, and row selector (RS) transistor 250A. FD region 225B is coupled to reset gate (RST) 230B, source follower (SF) transistor 240B, and row selector (RS) transistor 250B. Output 260 is coupled to the outputs of RS 250A and RS 250B. Output 260 may, accordingly, be a single output connected to both sets of pixel structures corresponding to sets of photodiodes (PD) 210A-D and PD 210I-L. In certain embodiments, photodiodes (PD) 210 and floating diffusion (FD) regions 225 are formed in a substrate of the pixel array while the gates/transistors are formed above the substrate (e.g., transfer gate (TG) 220, reset gate (RST) 230, source follower (SF) transistor 240, row selector (RS) transistor 250 are formed above the substrate).

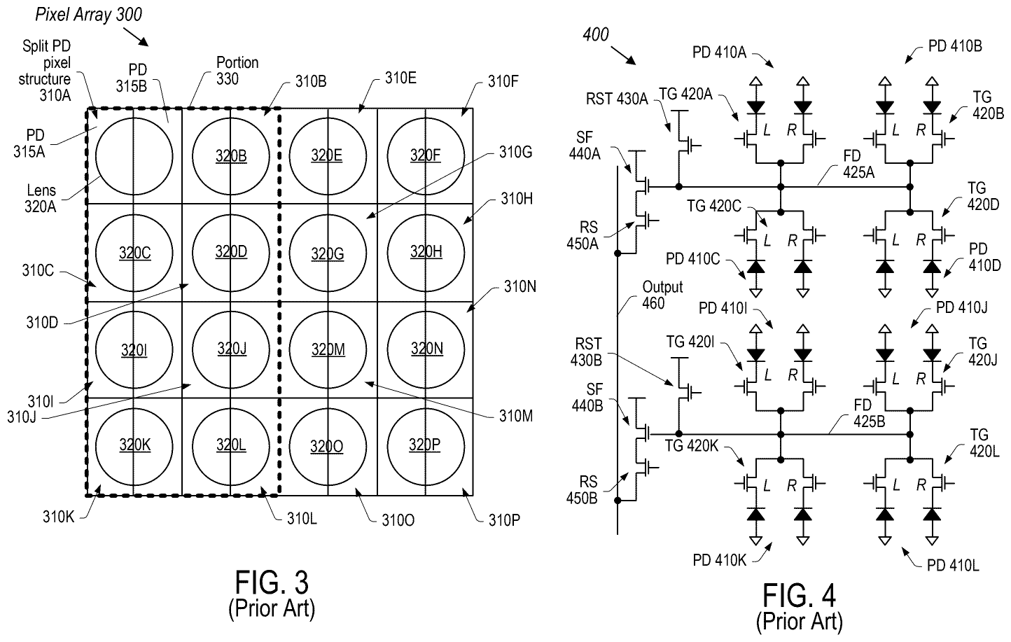

FIG. 3 is a top plan view of an example pixel array having split PD pixel structures, according to some embodiments. In the illustrated embodiment, pixel array 300 includes split PD pixel structures 310A-P. For split PD pixel structures 310, each split PD pixel structure 310 has two photodiodes (PD) 315A/315B inside its square-shaped perimeter. Thus, pixel array 300 has two photodiodes per square-shaped unit (square-shaped units being defined by the perimeter shape of pixel structures 310). Note that PD 315A/315B are only identified in split PD pixel structure 310A in FIG. 3 for simplicity in the drawing. In various embodiments, PD 315A and PD315B are rectangular-shaped photodiodes that occupy half of the area of a square-shaped unit of pixel structures 310. For instance, as shown in FIG. 3, PD 315A and PD 315B are separated by the vertical line passing through the center of split PD pixel structure 310A. Accordingly, the vertical lines through the remaining split PD pixel structures 310B-P may delineate the corresponding photodiodes in each pixel structure.

As with the square PD pixel structures of FIG. 1, each split PD pixel structure 310A-P includes a corresponding lens 320A-P in pixel array 300. Lens 320 may be, for example, a micro-lens or other lens structure for focusing light onto both photodiodes 315A/315B in split PD pixel structure 310. Pixel array 300, similar to pixel array 100, may be a color filter array having a combination of red (R) pixel structures, green (G) pixel structures, and blue (B) pixel structures (e.g., the color filter array is an RGB filter array). In the illustrated embodiment of FIG. 3, pixel structures 310A-D and 310M-P are green pixel structures, pixel structures 310E-H are blue pixel structures, and pixel structures 310I-L are red pixel structures. Thus, pixel array 300 includes 8 green pixel structures, 4 blue pixel structures, and 4 red pixel structures. It should be understood, however, that any number or combination of different color pixel structures may be implemented in pixel array 300.

With the implementation of split photodiodes (e.g., PD 315A and PD 315B) in each split PD pixel structure 310A-P, pixel array 300 supports PDAF. PDAF is supported intrinsically in pixel array 300 as the dual photodiodes in each pixel structure 310 allow for detecting signal differences between the left photodiode (e.g., PD 315A) and the right photodiode (e.g., PD 315B). The signal differences may be a function of the angle of incident light. Accordingly, phase and corresponding focus may be determined based on the signal differences between the left photodiode and the right photodiode.

FIG. 4 is an example schematic diagram for a portion of pixel array 300, according to some embodiments. In the illustrated embodiment, schematic diagram 400 is provided for portion 330 of pixel array 300 (shown by the dashed lines in FIG. 3). Portion 330, as shown in FIG. 3, includes pixel structures 310A-D and pixel structures 310I-L. As shown in FIG. 4, schematic diagram 400 includes photodiodes (PD) 410A-D and photodiodes (PD) 410I-L, which correspond to pixel structures 310A-D and pixel structures 310I-L from FIG. 3, respectively. Note that, in FIG. 4, each photodiode (PD) 410 includes a pair of photodiodes. For example, photodiodes (PD) 410 include a left (L) photodiode and a right (R) photodiode as designated by the symbols “L” and “R” in FIG. 4. Correspondingly, the left and right photodiode pairs in PD 410A-D and 4D 210I-L have their own corresponding left and right pairs of transfer gates (TG) 420A-D and TG 420I-L, respectively.

The left and right pairs of transfer gate (TG) 420A-D are coupled together at floating diffusion (FD) region 425A while the left and right pairs of transfer gate (TG) 420I-L are coupled together at floating diffusion (FD) region 425B. FD region 425A is coupled to reset gate (RST) 430A, source follower (SF) transistor 440A, and row selector (RS) transistor 450A. FD region 425B is coupled to reset gate (RST) 430B, source follower (SF) transistor 440B, and row selector (RS) transistor 450B. Output 460 is coupled to the outputs of RS 450A and RS 450B. Output 460 may, accordingly, be a single output connected to both sets of pixel structures corresponding to sets of pairs of photodiodes (PD) 410A-D and PD 410I-L.

As noted above, autofocus capability may be added to pixel array 100, with its implementation of square PD pixel structures 110, by adding optical shielding (or multi-pixel OCL) to some of the pixel structures. The added optical shielding is limited to a small portion of the overall area of pixel array 100 (e.g., about 10%) in order to maintain normal light sensing functions in the pixel array. Accordingly, pixel array 300, with its implementation of split PD pixel structures 310, may provide better autofocus performance (e.g., using PDAF) than pixel array 100 with optical shielding. Pixel array 300 may have better autofocus performance as 100% of the pixel structures (or close to) are used for autofocus detection while only the small portion (e.g., 10%) of pixel array 100 is usable for autofocus detection.

Pixel array 100, however, may have a larger photodiode detection area and simpler readout circuitry than pixel array 300 due to the use of square PD pixel structures 110. The larger photodiode detection area and simpler readout circuitry of square PD pixel structures 110 may provide better signal-to-noise, better dynamic range, and response uniformity than is available when split PD pixel structures 310 are implemented. As current devices implement either a pixel array of square PD pixel structures or a pixel array of split PD pixel structures, image sensor designers often have to make a decision as to which pixel array is used in a particular device based on the trade-offs of using one type of pixel structure or the other.

To address these current challenges in implementing pixel arrays in image sensors, the present disclosure contemplates embodiments of pixel arrays that implement both square PD pixel structures and split PD pixel structures along with corresponding operations of such pixel arrays. Having a combination (e.g., hybrid structure) of square PD pixel structures and split PD pixel structures may address the performance trade-offs of having only one or the other type of pixel structures. For instance, a hybrid pixel array structure with both square PD pixel structures and split PD pixel structures may be capable of autofocus with better performance than a square PD pixel-only pixel array structure while also having higher signal-to-noise, better dynamic range, and response uniformity than a split PD pixel-only pixel array structure. Hybrid pixel array structures, as described herein, may have various arrangements of square PD pixel structures and split PD pixel structures. The arrangements may further include variations in color options for the different PD pixel structures. Timing schemes for reading out signals from the hybrid pixel array structures are also described herein.

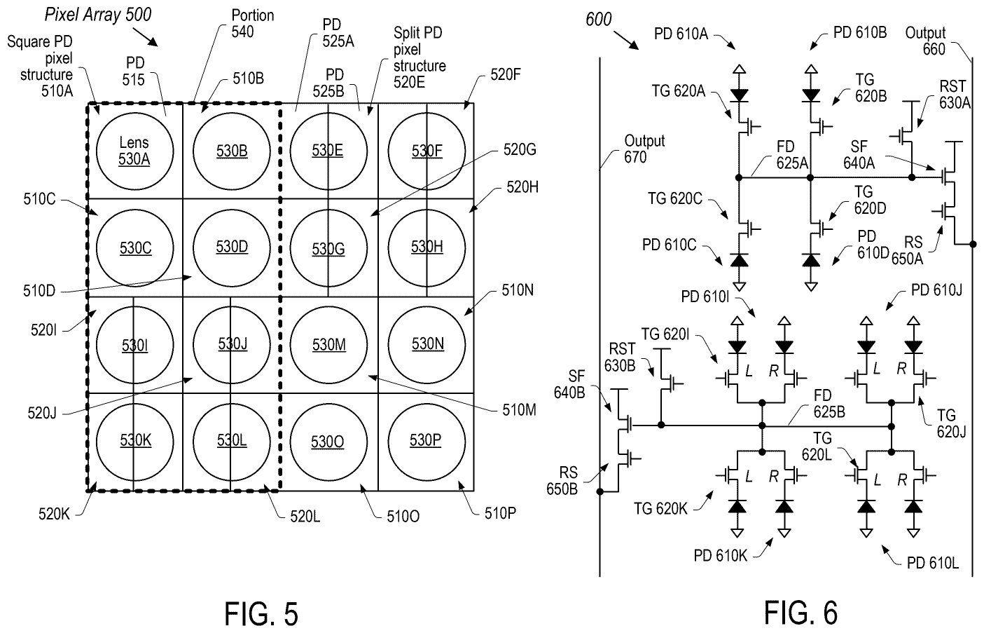

FIG. 5 is a top plan view of a contemplated hybrid pixel array, according to some embodiments. In certain embodiments, pixel array 500 includes photodiodes and other components formed in a substrate such as a silicon substrate. In various embodiments, pixel array 500 is part of an image sensor on an image capturing device. The image sensor may be part of devices including, but not limited to, cameras, mobile devices (e.g., smart phones, tablets, laptops, etc.), robotic equipment, or security monitoring devices.

In the illustrated embodiment, pixel array 500 includes two sets of square PD pixel structures—square PD pixel structures 510A-D and square PD pixel structures 510M-α-along with two sets of split PD pixel structures-split PD pixel structures 520E-H and split PD pixel structures 520I-L. Square PD pixel structures 510 include one photodiode (PD) 515 inside the square-shaped perimeter of the pixel structures while split PD pixel structures 520 include two photodiodes-PD 525A and PD 525B-inside the square-shaped perimeter of the pixel structures. Thus, pixel array 500 includes both pixel structures with one photodiode per square-shaped unit and pixel structures with two photodiodes per square-shaped unit. Note that PD 515 is only identified in square PD pixel structure 510A in FIG. 5 for simplicity in the drawing. Similarly, PD 525A and PD 525B are only identified in split PD pixel structure 520E in FIG. 5. In various embodiments, PD 515 is a square-shaped photodiode that occupies an entire area of a square-shaped unit of pixel structures 510 while PD 525A and PD 525B are rectangular-shaped photodiodes that occupy half of the area of a square-shaped unit of pixel structures 520. As shown in FIG. 5, PD 525A and PD 525B are separated by the vertical line passing through the center of split PD pixel structure 520E. Accordingly, the vertical lines through the remaining split PD pixel structures 520F-L may delineate the corresponding photodiodes in each split PD pixel structure.

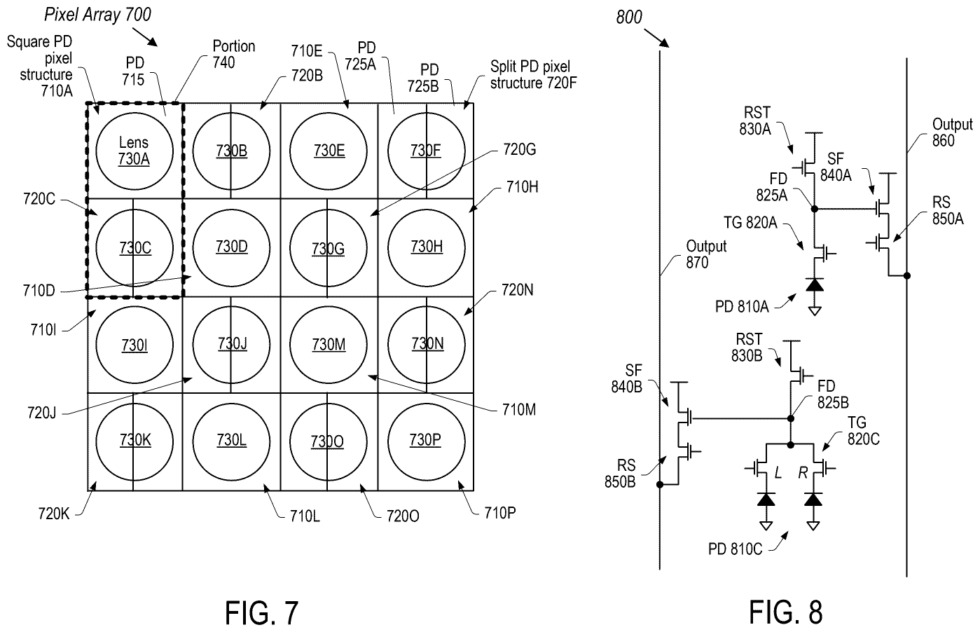

In various embodiments, both square PD pixel structures 510A-D and 510M-P and split PD pixel structures 520E-L have corresponding lens 530A-P in pixel array 500. Lens 530 may be, for example, a micro-lens or other lens structure for focusing light onto the photodiode(s) in the pixel structures. In certain embodiments, pixel array 500 is a color filter array having a combination of red (R) pixel structures, green (G) pixel structures, and blue (B) pixel structures (e.g., the color filter array is an RGB filter array). In some embodiments, square PD pixel structures 510 are green pixel structures while split PD pixel structures 520 are used for blue or red pixel structures. Other embodiments may be contemplated where square PD pixel structures 510 and/or split PD pixel structures 520 are other color pixel structures than those described herein. For instance, embodiments may be contemplated with monochrome pixel structures, clear pixel structures, or yellow pixel structures (such as in a red/yellow/blue image sensor). Additionally, the locations and pattern of square PD pixel structures 510 and split PD pixel structures 520 in a pixel array may be varied from the locations and patterns shown by example in FIG. 5 (and FIG. 7 described below). The pattern of square PD pixel structures 510 and split PD pixel structures 520 may be a regular pattern or an irregular pattern.

In the illustrated embodiment of FIG. 5, pixel array 500 is a Quadra color filter array (CFA). For the Quadra CFA, pixel array 500 includes a total of eight square PD pixel structures 510A-D and 510M-P that are green pixel structures, four split PD pixel structures 520E-H that are blue pixel structures, and four split PD pixel structures 520I-L that are red pixel structures. As noted above, pixel array 500 may have a higher number of green pixels to increase the signal response to green light versus blue or red light. This pattern of pixel array 500 may be repeated over a large number of pixel arrays to form a larger pixel array for implementation as a Quadra CFA in an image sensor. Embodiments may be contemplated where the number of square PD pixel structures and the number of split PD pixel structures are not equal across a pixel array. For instance, in a Quadra CFA, the repeating pattern may include twelve (12) split PD pixel structures and four (4) square PD pixel structures. In such an embodiment, some of the split PD pixel structures may be green pixel structures to enable higher green light sensitivity.

FIG. 6 is an example schematic diagram for a portion of pixel array 500, according to some embodiments. In the illustrated embodiment, schematic diagram 600 is provided for portion 540 of pixel array 500 (shown by the dashed lines in FIG. 5). Portion 540, as shown in FIG. 5, includes square PD pixel structures 510A-D and split PD pixel structures 520I-L. As shown in FIG. 6, schematic diagram 600 includes photodiodes (PD) 610A-D and photodiodes (PD) 610I-L, which correspond to square PD pixel structures 510A-D and split PD pixel structures 520I-L from FIG. 5, respectively. Note that, in FIG. 6, photodiodes (PD) 610A-D include a single photodiode while photodiodes 610I-L include pairs of photodiodes denoted as a left (L) photodiode and a right (R) photodiode by the symbols “L” and “R” in FIG. 6. Photodiodes 610A-D have their corresponding target gates (TG) 620A-D while photodiodes 610I-L have corresponding left and right pairs of transfer gates (TG) 620I-L.

The transfer gates (TG) 620A-D are coupled together at floating diffusion (FD) region 625A while the left and right pairs of transfer gates (TG) 620I-L are coupled together at floating diffusion (FD) region 625B. FD region 625A is coupled to reset gate (RST) 630A, source follower (SF) transistor 640A, and row selector (RS) transistor 650A. Output 660 is coupled to the output of RS 650A to provide an output from the square PD pixel structures corresponding to photodiodes (PD) 610A-D. FD region 625B is coupled to reset gate (RST) 630B, source follower (SF) transistor 640B, and row selector (RS) transistor 650B. Output 670 is coupled to the output of RS 650B to provide an output from the split PD pixel structures corresponding to L/R pairs of photodiodes (PD) 610I-L. Outputs 660 and 670 may, accordingly, be separate outputs for the two different types of pixel structures implemented in pixel array 500—square PD pixel structures and split PD pixel structures. Having separate outputs from the different types of pixel structures may enable the pixel structures to be addressed to and readout from separately, as described herein. Separating the signal outputs between the different types of pixel structures may allow separate signal processing (e.g., analog-to-digital conversion) for the readout signals to be implemented. Separating the addressing of the different types of pixel structures may allow separate row addressing units and timing signals to be provided to the different types of pixel structures. Address to and readout from may also, in some contemplated embodiments, be handled through a single output.

FIG. 7 is a top plan view of another contemplated hybrid pixel array, according to some embodiments. In certain embodiments, pixel array 700 includes photodiodes and other components formed in a substrate such as a silicon substrate. In various embodiments, pixel array 700 is part of an image sensor on an image capturing device. The image sensor may be part of devices including, but not limited to, cameras, mobile devices (e.g., smart phones, tablets, laptops, etc.), robotic equipment, or security monitoring devices.

In the illustrated embodiment, pixel array 700 includes an alternating pattern of square PD pixel structures 710 and split PD pixel structures 720. The basic alternating pattern is a set of four pixels (such as pixel units A-D) that includes two square PD pixel structures at opposing corners (e.g., square PD pixel structures 710A/D) and two split PD pixel structures at opposing corners (e.g., split PD pixel structures 720B/C). This basic pattern may be repeated over the entire pixel array 700 to form an alternating pattern that includes square PD pixel structures 710A/D/E/H/I/L/M/P and split PD pixel structures 720B/C/F/G/J/K/N/O, as shown in FIG. 7. As with pixel array 500, square PD pixel structures 710 include one photodiode (PD) 715 inside the square-shaped perimeter of the pixel structures while split PD pixel structures 720 include two photodiodes-PD 725A and PD 725B-inside the square-shaped perimeter of the pixel structures. Thus, pixel array 700 includes alternating pixel structures with one photodiode per square-shaped unit and pixel structures with two photodiodes per square-shaped unit. Note that PD 715 is only identified in square PD pixel structure 710A and PD 725A and PD 725B are only identified in split PD pixel structure 720F in FIG. 7 for simplicity in the drawing. In various embodiments, both square PD pixel structures 710A/D/E/H/I/L/M/P and split PD pixel structures 720B/C/F/G/J/K/N/O have corresponding lens 730A-P in pixel array 700.

In certain embodiments, pixel array 700 is a color filter array having a combination of red (R) pixel structures, green (G) pixel structures, and blue (B) pixel structures (e.g., the color filter array is an RGB filter array). In some embodiments, square PD pixel structures 710 are green pixel structures while split PD pixel structures 720 are used for blue or red pixel structures. In the illustrated embodiment of FIG. 7, pixel array 700 is a Bayer color filter array (CFA). For the Bayer CFA, pixel array 700 includes a total of eight square PD pixel structures 710A/D/E/H/I/L/M/P that are green pixel structures, four split PD pixel structures 720B/F/J/N that are blue pixel structures, and four split PD pixel structures 720C/G/K/O that are red pixel structures. The basic alternating pattern for the Bayer CFA is a set of four pixels that includes two green pixel structures at opposing corners (e.g., square PD pixel structures 710A/D) and blue and red pixels structures at opposing corners (e.g., split PD pixel structure 720B is a blue pixel and split PD pixel structures 720C is a red pixel). As with pixel array 500, pixel array 700 may have a higher number of green pixels to increase the signal response to green light versus blue or red light. The alternating pattern of pixel array 700 may be repeated over a large number of pixel arrays to form a larger pixel array for implementation as a Bayer CFA in an image sensor.

FIG. 8 is an example schematic diagram for a portion of pixel array 700, according to some embodiments. In the illustrated embodiment, schematic diagram 800 is provided for portion 740 of pixel array 700 (shown by the dashed lines in FIG. 7). Portion 740, as shown in FIG. 5, includes square PD pixel structure 710A and split PD pixel structure 720C. As shown in FIG. 8, schematic diagram 800 includes photodiode (PD) 810 and photodiode (PD) 810C, which correspond to square PD pixel structure 710A and split PD pixel structure 720C from FIG. 7, respectively. Photodiode (PD) 810A includes a single photodiode while photodiode 810C includes a pair of photodiodes denoted as a left (L) photodiode and a right (R) photodiode by the symbols “L” and “R” in FIG. 8. Photodiode 810A has its corresponding target gate (TG) 820A while photodiode 810C has its corresponding left and right pairs of transfer gates (TG) 820C.

Transfer gate (TG) 820A is coupled to floating diffusion (FD) region 825A while the left and right pairs of transfer gates (TG) 820C are coupled together and to floating diffusion (FD) region 825B. FD region 825A is coupled to reset gate (RST) 830A, source follower (SF) transistor 840A, and row selector (RS) transistor 850A. Output 860 is coupled to the output of RS 850A to provide an output from the square PD pixel structure corresponding to photodiode (PD) 810A. FD region 825B is coupled to reset gate (RST) 830B, source follower (SF) transistor 840B, and row selector (RS) transistor 850B. Output 870 is coupled to the output of RS 850B to provide an output from the split PD pixel structure corresponding to the L/R pairs of photodiodes (PD) 810C. Outputs 860 and 870 may, accordingly, be separate outputs for the two different types of pixel structures implemented in pixel array 700—square PD pixel structures and split PD pixel structures.

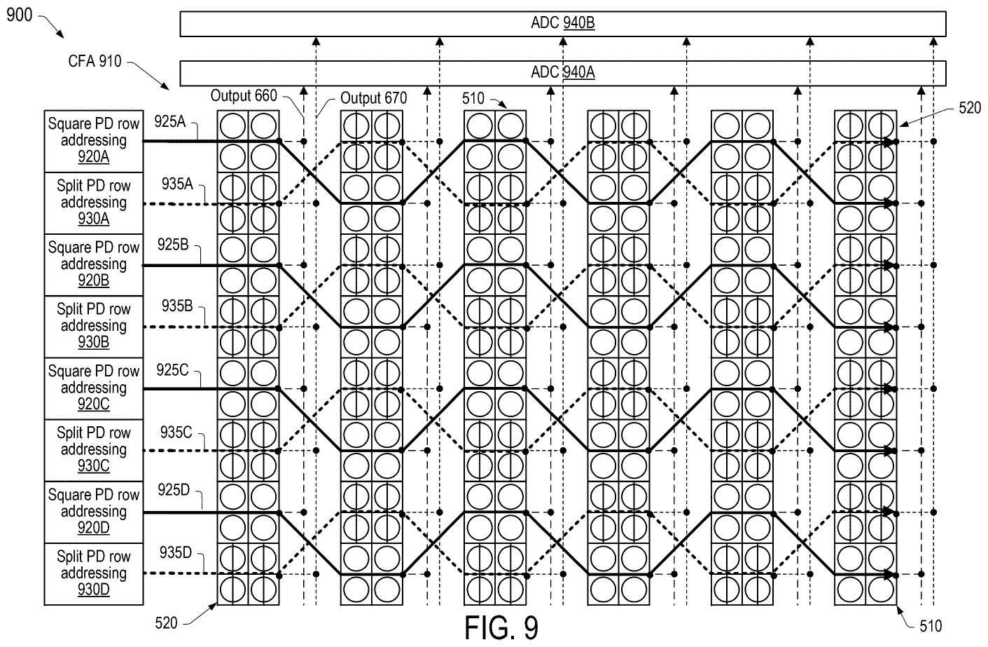

FIG. 9 is a circuit layout for addressing and readout of a pixel array, according to some embodiments. Circuit layout 900 is an example of one contemplated embodiment for addressing and readout of a large pixel array formed by a repeating pattern of pixel array 500, shown in FIG. 5. Thus, in certain embodiments, circuit layout 900 is a contemplated circuit layout for a Quadra CFA that implements a combination of square PD pixel structures and split PD pixel structures. While circuit layout 900 depicts one example of a circuit layout for addressing and readout of a Quadra CFA, it should be understood that additional embodiments for addressing and readout may be contemplated within the scope of the present disclosure.

In the illustrated embodiment, circuit layout 900 includes Quadra CFA 910. CFA 910 includes a pattern of square PD pixel structures 510 and split PD pixel structures 520. The pattern of square PD pixel structures 510 and split PD pixel structures 520 may, for example, be based on the pattern of pixel structures in pixel array 500 (shown in FIG. 5). For simplicity in the drawing, not all square PD pixel structures 510 and split PD pixel structures 520 are labelled in FIG. 9. Nevertheless, as previously shown and described throughout the present disclosure, square PD pixel structures 510 are represented by circles inside squares in FIG. 9 while split PD pixel structures 520 are represented by circles inside squares with vertical lines splitting the squares and circles in half (representing the split photodiodes in the pixel structures). In certain embodiments, CFA 910 further includes the pattern of green pixel structure, red pixel structures, and blue pixel structures of pixel array 500 (shown in FIG. 5).

In various embodiments, circuit layout 900 includes multiple square PD pixel structure row addressing circuits 920 and multiple split PD pixel structure row addressing circuit 930 coupled to CFA 910. In the illustrated embodiment of FIG. 9, there are four square PD pixel structure row addressing circuits 920A-D and four split PD pixel structure row addressing circuit 930A-D. Square PD pixel structure row addressing circuits 920A-D are coupled to square PD pixel structures 510 by circuit lines 925A-D (solid lines) and split PD pixel structure row addressing circuit 930A-D are coupled to split PD pixel structures 520 by circuit lines 935A-D (dashed lines). As depicted in FIG. 9, circuit lines 925A-D and circuit lines 935A-D may zig-zag back and forth between offset square PD pixel structures 510 and offset split PD pixel structures 520, respectively. Having circuit lines 925A-D and circuit lines 935A-D zig-zag between offset pixel structures allows control signal timing (e.g., row addressing) to be identical for all the pixel structures along a same row. For instance, all the square PD pixel structures 510 coupled to square PD row addressing circuit 920A by zig-zag circuit line 925A have the same timing based on receiving the same control signal. Similarly, all the split PD pixel structures coupled to split PD row addressing circuit 930A by zig-zag circuit line 935A have the same timing based on receiving the same control signal.

In addition to different row addressing circuits, circuit layout 900 includes two analog-to-digital conversion (ADC) circuits 940A and 940B. ADC circuit 940A is coupled to outputs 660 from square PD pixel structures 510 (note that output 660 is also shown in the schematic diagram of FIG. 6). ADC circuit 940B is coupled to outputs 670 from split PD pixel structures 520 (note that output 670 is also shown in the schematic diagram of FIG. 6). Separate readout paths may be necessary because the timing of readouts from square PD pixel structures 510 is slightly different from the timing of readouts from split PD pixel structures 520 (e.g., square PD pixel structures 510 have readouts from a single photodiode while split PD pixel structures 520 have readouts from a pair of photodiodes). Thus, having separate ADC circuits for the different types of pixel structures allows readout signals to be read in parallel. For instance, readout signals from outputs 660 of square PD pixel structures 510 may be read by ADC circuit 940A in parallel with readout signals from output 670 of split PD pixel structures 520 read by ADC circuit 940B. This parallel readout scheme may be more efficient in obtaining readouts from the hybrid pixel array structures described herein. Some embodiments may be contemplated where a single ADC circuit performs readout from both square PD pixel structures 510 and split PD pixel structures 520. Such a single ADC circuit may conduct the readouts in series due to the different nature of photodiodes being read out by the ADC circuit (e.g., readouts from a single photodiode versus a pair of photodiodes in each pixel structure).

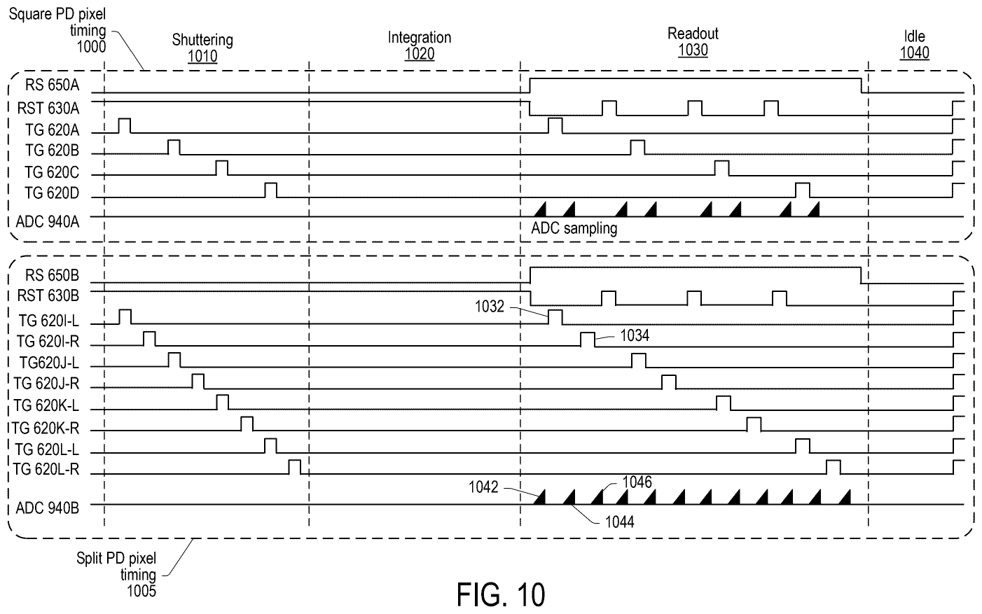

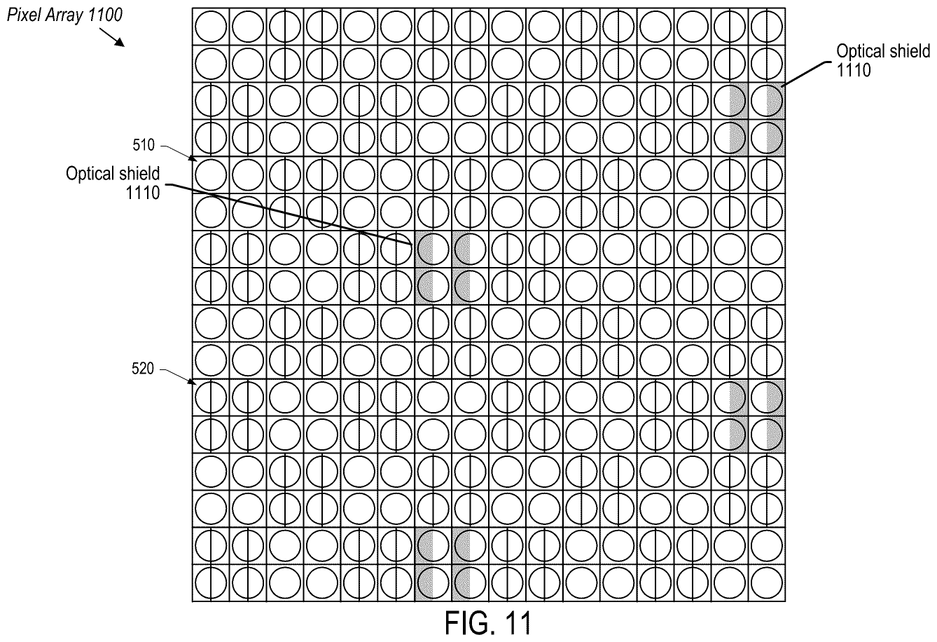

FIG. 10 depicts a timing diagram for operation of transistors in pixel arrays, according to some embodiments. In the illustrated embodiment, there are two sets of timing implemented—square PD pixel timing 1000 and split PD pixel timing 1005. Square PD pixel timing 1000 is implemented for a set of four square PD pixel structures represented by the curves for four transfer gate (TG) transistors—TG 620A, TG 620B, TG 620C, TG 620D. As shown in FIG. 6, these four transfer gate (TG) transistors are coupled to reset gate (RST) transistor 630A and row selection (RS) transistor 650A, which also have corresponding curves in the timing diagram. Outputs of the square PD pixel structures are provided to ADC 940A (shown in FIG. 9), which has a corresponding curve in the timing diagram.

Split PD pixel timing 1005 is implemented for a set of four split PD pixel structures represented by the curves for eight transfer gate (TG) transistors (four left and four right TG transistors)—TG 620I-L, TG 620I-R, TG 620J-L, TG 620J-R, TG 620K-L, TG 620K-R, TG 620L-L, and TG 620L-R. As shown in FIG. 6, these eight transfer gate (TG) transistors are coupled to reset gate (RST) transistor 630B and row selection (RS) transistor 650B, which also have corresponding curves in the timing diagram. Outputs of the splits PD pixel structures are provided to ADC 940B (shown in FIG. 9), which has a corresponding curve in the timing diagram

During operation of the pixel array, the pixels (e.g., pixel structures) may go through 4 (four) time periods of operation-shuttering 1010, integration 1020, readout 1030, and idle 1040. Shuttering 1010 is a time period of operation during which all photoelectrons are drained out from photodiodes (e.g., the photodiodes are reset). Integration 1020 is a time period of operation during which photoelectrons are accumulated in the photodiodes (e.g., by exposing the photodiodes to light to generate photoelectrons and inhibiting photoelectrons from transferring out of the photodiodes). Readout 1030 is a time period of operation during which signals are readout from the pixel structures. During readout 1030, photoelectrons are transferred out of the photodiodes into floating diffusion (FD) regions through the transfer gates (TG). Idle 1040 is a time period of operation during which the pixel array idles after readout 1030 and before resetting of the photodiodes in shuttering 1010. It should be noted that the time periods shuttering 1010, integration 1020, readout 1030, and idle 1040 are substantially the same for both square PD pixel timing 1000 and split PD pixel timing 1005.

As shown in the timing diagram of FIG. 10, shuttering 1010 includes a pulse of the transfer gates (TG) (TG 620A-L) while the reset transistors (RST 630A and RST 630B) are turned on to pass photoelectrons through these transistors while the row selection transistors (RS 650A and RS 650B) are turned off. This shuttering can be done for both the square PD pixel structures and the split PD pixel structures. Any photoelectrons released during the pulses of the TG transistors are transferred to a drain (e.g., a Vdd) through the reset transistors. The pulses of the TG transistors may be set to be long enough to drain all photoelectrons from the photodiodes.

After resetting the photodiodes in shuttering 1010, operation of the pixels may switch to integration 1020. During integration, the photodiodes are exposed to light to generate photoelectrons in the photodiodes. This operation is to accumulate photoelectrons in the photodiodes to later generate signals for readout from the pixel structures. Thus, during integration 1020, the TG transistors are kept off to inhibit photoelectrons from transferring through the TG transistors. The reset transistors may be left on to allow any photoelectrons that may pass through the TG transistors to pass to the drain.

After accumulation of photoelectrons in integration 1020, the operation of the pixel array shifts to readout 1030. In readout 1030, the reset transistors (RST 630A and RST 630B) are turned off and the TG transistors (TG 620A-L) are pulsed for various short periods to transfer photoelectrons from the photodiodes to the FD regions. The FD regions accumulate charges from the photoelectrons that are then readout as an analog signal from the pixel array to the ADC circuits (ADC 940A and ADC 940B). To allow the analog signals to be readout, the row selection transistors (RS 650A and RS 650B) are turned on, which allows the analog signals to transfer from the FD regions to outputs 660 and 670 at the drain of the row selection transistors (as shown in FIG. 6).

As shown in the illustrated embodiment, the readouts for square PD pixel timing 1000 and split PD pixel timing 1005 may be different due to the different structures of square PD pixel structures and split PD pixel structures. For instance, as the square PD pixel structures only have single photodiodes and corresponding transfer gates (TG 620A-D), individual transfer gate may be pulsed once and the ADC is sampled twice (shown as black triangles along ADC 940A), once before the pulse and once after the pulse. The first sample before the TG pulse represents the baseline level while the second sample after the TG pulse represents the signal level based on the accumulation of photoelectrons in the photodiode associated with the TG. The level of the signal for the photodiodes is then determined based on subtracting the baseline level from the signal level readout from each transfer gate (TG) transistor. Note that the reset transistor (RST 630A) is pulsed between samplings of different transfer gate (TG) transistors to reset the baseline level between TG pulses.

As the split PD pixel structures have two photodiodes (left and right pairs) and corresponding transfer gates (TG 620I-L (and L/R)), left and right pairs of transfer gate (TG) transistors may be pulsed separately between reset transistor (RST 630B) pulses. Thus, for each pair of left and right photodiodes in a single split PD pixel structure, the ADC (ADC 940B) samples the signal three times (shown as black triangles along ADC 940B)—once before the first TG pulse of one photodiode (either left or right), once after the first TG pulse, and once after the second TG pulse of the other photodiode). The first sample before the first TG pulse represents the baseline level while the second sample after the first TG pulse represents the signal level based on the accumulation of photoelectrons in the first photodiode associated with the TG pulse and the third sample after the second TG pulse represents the signal level based on the accumulation of photoelectrons in the second photodiode associated with the second TG pulse. The level of the signal for the first photodiode is determined based on subtracting the baseline level from the second sample signal level readout after the first TG pulse while the level of the signal for the second photodiode is determined based on subtracting the baseline level and the second sample signal level readout from the third sample signal level readout after the second TG pulse.

As an example for the pair of photodiodes associated with TG 620I-L and TG 620I-R, readout 1030 begins with the first readout sample 1042 of ADC 940B before the first TG pulse 1032. Second readout sample 1044 is then taken after first TG pulse 1032 and before second TG pulse 1034. Third readout sample 1046 is then taken after second TG pulse 1034. Reset transistor (RST 630B) is then pulsed to reset the signal level to baseline before readout of the pair of photodiodes associated with TG 620J-L and TG 620J-R.

To maintain synchronous overall timing for readout 1030 between square PD pixel timing 1000 and split PD pixel timing 1005, the pulsing of reset transistors (RST 630A and RST 630B) may be synchronous. Accordingly, split PD pixel timing 1005 provides timing for readouts of both photodiodes in a split PD pixel structure that is synchronous with the timing for a readout of a single photodiode in a square PD pixel structure. Maintaining this synchronous overall timing allows a single overall timing circuit to be implemented for the timing diagram. For example, a single timing control circuit may apply timing for shuttering 1010, integration 1020, readout 1030, and idle 1040 of both types of pixel structures. Utilizing a single timing control circuit may reduce the complexity of circuits involved with implementing a hybrid pixel array structure as described herein.

FIG. 11 is a top plan view of yet another contemplated hybrid pixel array, according to some embodiments. In the illustrated embodiment, pixel array 1100 includes a pattern of square PD pixel structures 510 and split PD pixel structures 520. The pattern of square PD pixel structures 510 and split PD pixel structures 520 may, for example, be based on the pattern of pixel structures in pixel array 500 (shown in FIG. 5) or pixel array 700 (shown in FIG. 7). For simplicity in the drawing, not all square PD pixel structures 510 and split PD pixel structures 520 are labelled in FIG. 11. Nevertheless, as previously shown and described throughout the present disclosure, square PD pixel structures 510 are represented by circles inside squares in FIG. 11 while split PD pixel structures 520 are represented by circles inside squares with vertical lines splitting the squares and circles in half (representing the split photodiodes in the pixel structures). In certain embodiments, pixel array 1100 further includes any pattern of green pixel structure, red pixel structures, and blue pixel structures contemplated by the present disclosure.

In certain embodiments, pixel array 1100 includes optical shielding elements 1110 placed over one or more square PD pixel structures 510. Optical shielding elements 1110 may include, for example, optical shielding formed on a backside of the pixel structures (such as in a backside-illuminated process) or multi-pixel on-chip lens (OCL). Material for optical shielding elements 1110 may include, but not be limited to, tungsten or other light absorption metals. As shown in FIG. 11, optical shielding elements 1110 may be positioned on one-half the area of square PD pixel structures 510. For instance, optical shielding elements 1110 may be positioned on either a left or right half of square PD pixel structures 510.

The addition of optical shielding elements 1110 to square PD pixel structures 510 may enable different modes of operation and/or additional options for autofocus (e.g., PDAF) for an image sensor with pixel array 1100. For instance, optical shielding elements 1110 may enable modes of autofocus operation that utilize less power by allowing split PD pixel structures to be turned off during particular autofocus modes. As another example, optical shielding elements 1110 may provide capability for sub-sampling of light signals. Sub-sampling may enable deeper interpretation of photoelectron accumulation results for generating images.

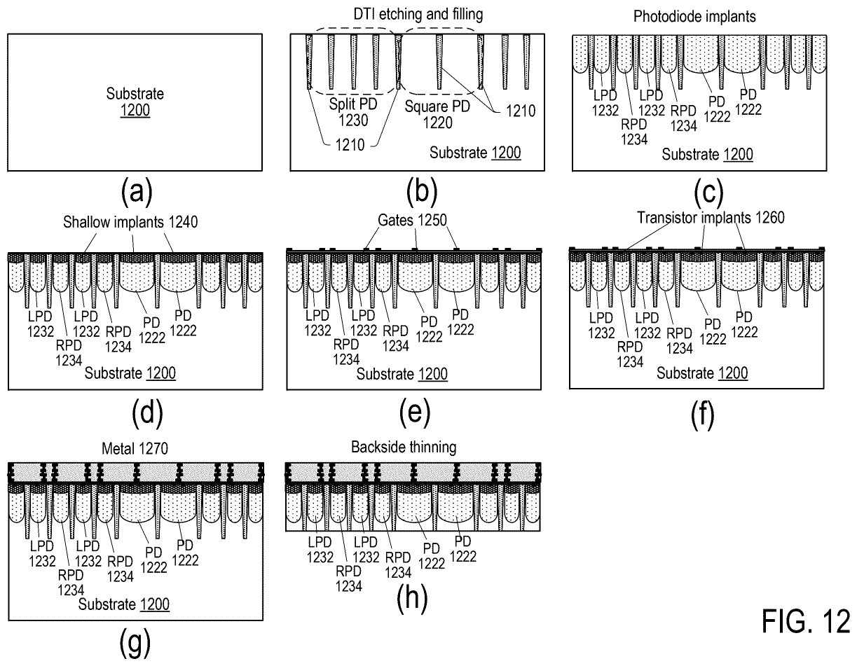

FIG. 12 is an example process flow for forming a hybrid pixel array structure, according to some embodiments. The illustrated process flow displays various possible steps for forming a hybrid pixel array structure on a single substrate. In the illustrated embodiment, the process flow begins at (a) with substrate 1200. Substrate 1200 may be, for example, a silicon substrate though other substrates may be contemplated. In (b), deep trench isolation (DTI) or another isolation trench formation method may be implemented to form trenches 1210 in substrate 1200. In some embodiments, trenches 1210 are filled with an isolation material. In certain embodiments, trenches 1210 are formed with a single mask. Trenches 1210 may be formed to define implant areas/regions for photodiodes of square PD pixel structures 1220 and for photodiodes of split PD pixel structures 1230. As shown in FIG. 12, the density of trenches 1210 is different for square PD pixel structures 1220 and split PD pixel structures 1230. Pixel arrays with DTI trenches 1210 may have improved pixel-pixel optical and electrical isolation.

After formation of trenches 1210, the process flow continues in (c) with implanting photodiodes for the pixel structures. Implanting photodiodes may include forming photodiodes (PD) 1222 for square PD pixel structures 1220 and left photodiodes (LPD) 1232 and right photodiodes (RPD) 1234 for split PD pixel structures 1230. In some embodiments, a single mask may be used to form photodiodes (PD) 1222 along with left photodiodes (LPD) 1232 and right photodiodes (RPD) 1234. In other embodiments, two (or more) masks may be used. For instance, a first mask may be used to form photodiodes (PD) 1222 and a second mask is used to form left photodiodes (LPD) 1232 and right photodiodes (RPD) 1234. Two or more masks may be used, for instance, when additional implantation is not shared between the different photodiodes. In some embodiments, doping of epitaxial silicon may be implemented to form the photodiodes instead of implantation.

After the formation of implants in (c), shallow implants 1240 may be formed in (d). Shallow implants 1240 may include implantation of different materials from the materials implanted in (c) at shallow depths below the surface of substrate 1200. As with the deep implants, a single mask or a combination of two or more masks may be used for formation of shallow implants 1240 depending on whether there are any differences in implantation between square PD pixel structures and split PD pixel structures. After formation of shallow implants 1240, gates 1250 may be formed on the surface of substrate 1200 in (c). Gates 1250 may be formed with a single mask process unless different types of gates are necessary for the different photodiodes. Gates 1250 may include, for example, the various transfer gates (TG), reset transistors (RST), or row selection (RS) transistors described herein.

In (f), transistor implants 1260 are formed in shallow implants 1240. As with the other implants, a single mask or a combination of two or more masks may be used for formation of transistor implants 1260 depending on whether there are any differences in implantation between square PD pixel structures and split PD pixel structures. In (g), metallization 1270 is formed on the surface of substrate 1200. Metallization 1270 includes the various routing and connections made to gates 1250 for operation of the pixel structures. For instance, metallization may include routings to ADC circuit or row addressing circuits.

After metallization in (g), backside thinning may be performed in (h) to remove excess portions of substrate 1200 from the backside of the pixel array. In some embodiments, various backend metal patterning may be implemented after backside thinning. Backend metal patterning may include, for example, optical shield patterning or other optical metal patterning. Backend metal patterning may be similar for both square PD pixel structures and split PD pixel structures or may be different between the different types of pixel structures.

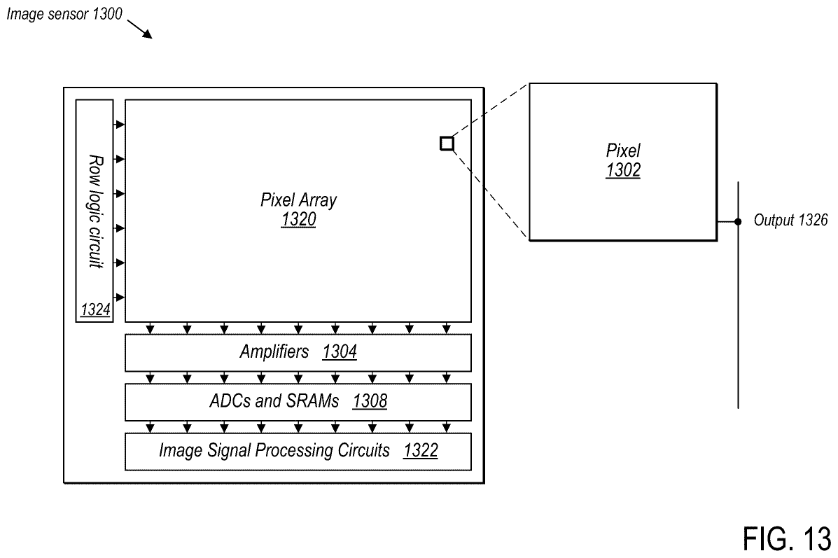

FIG. 13 is a schematic diagram of an example image sensor, according to some embodiments. As shown in FIG. 13, image sensor 1300 may include a plurality of light-gathering pixels 1302 (e.g., square PD pixel structures or split PD pixel structures as described herein) organized as a pixel array 1320. In some embodiments, image sensor 1300 may include one or more amplifiers 1304, one or more ADC (analog-to-digital conversion) circuits and memory 1308, and one or more image signal processing circuits 1322. In various embodiments, image signal processing circuits include data interface circuits. In some embodiments, image signals of pixels 1302 of pixel array 1320 may be read out row-by-row or column-by-column (or even pixel-by-pixel). For purposes of illustration, in this example, image sensor 1300 may also include row logic circuit 1324 to provide control signals to perform row-by-row readout of pixels 1302. Using the row-by-row readout, pixels 1302 on the same row may be read out at or around the same time, whereas pixels 1302 on the same column but different rows may be read out sequentially one row after another.

In some embodiments, the above readout of image signals of pixels 1302 may be implemented using one or more readout circuits, as described herein. For example, at least some of pixels 1302 may include one or more photodiodes and a pixel readout circuit. The photodiodes may generate and accumulate photoelectrons when exposed to light. During readout, under control signals from row logic circuit 1324, a row selection transistor and a source follower transistor may be turned on and release analog signal output through output 1326. Output 1326 may be coupled to a floating diffusion region that, depending on the state of a transfer gate and a reset gate may output an analog output signal with a reset value or a signal value.

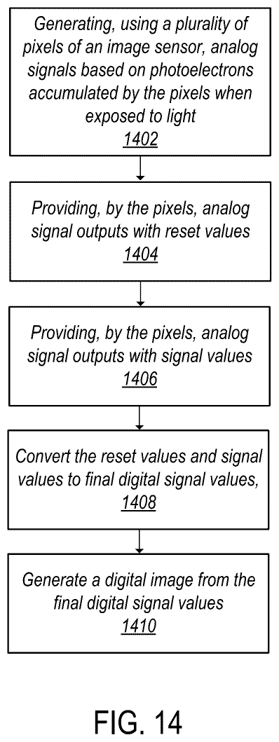

FIG. 14 is a flowchart showing an example method for processing image signals of an image sensor to generate a digital image, according to some embodiments. In FIG. 14, in some embodiments, in a photodiode of at least one pixel on an image sensor, photoelectrons are accumulated in response to the at least one pixel being exposed to light, as shown by block 1402. During readout, these photoelectrons may transfer out of the photodiodes to generate analog signal outputs (e.g., analog voltage outputs) at FD regions of the pixels, which may be further accessed at the output of the pixels. In FIG. 14, in some embodiments, the pixels provide analog signal outputs with reset values at block 1404. At block 1406, the pixels provide analog signal outputs with signal values. Then, at block 1408, the reset values and the signal values are converted to final digital signal values. In various embodiments, the final digital signal values are generated by a combination of ADCs, SRAMs, digital processing circuits, and data interface circuits. At block 1410, a digital image is generated from the final digital signal values. For example, digital processing circuits and/or data interface circuits may generate the digital image from the final digital signal values.

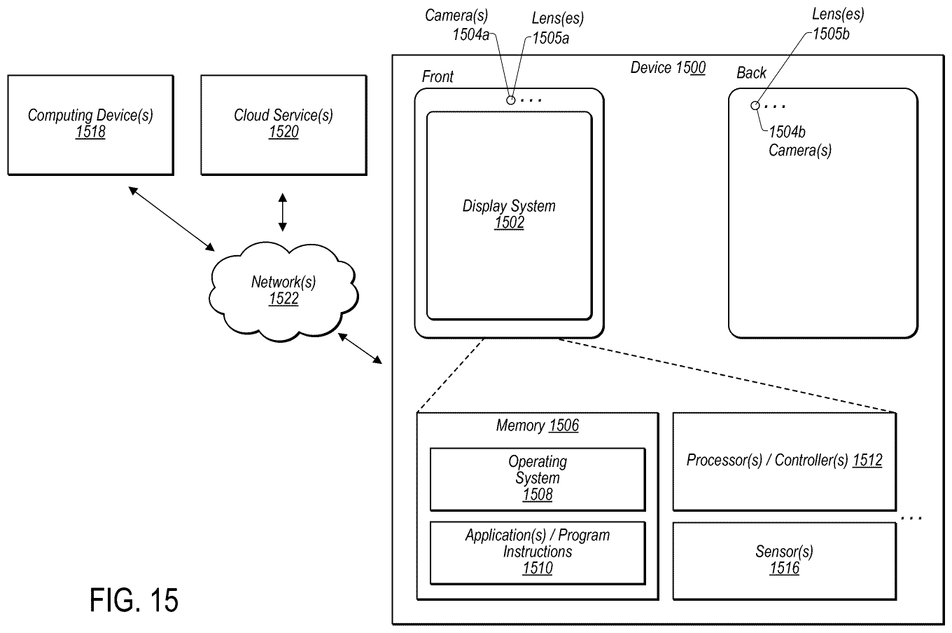

FIG. 15 illustrates a schematic representation of an example device 1500 that may include an image capturing device (e.g., a camera) having an image sensor, according to some embodiments. In some embodiments, the device 1500 may be a mobile device and/or a multifunction device. In various embodiments, the device 1500 may be any of various types of devices, including, but not limited to, a personal computer system, desktop computer, laptop, notebook, tablet, slate, pad, or netbook computer, mainframe computer system, handheld computer, workstation, network computer, a camera, a set top box, a mobile device, an augmented reality (AR) and/or virtual reality (VR) headset, a consumer device, video game console, handheld video game device, application server, storage device, a television, a video recording device, a peripheral device such as a switch, modem, router, or in general any type of computing or electronic device.

In some embodiments, the device 1500 may include a display system 1502 (e.g., comprising a display and/or a touch-sensitive surface) and/or one or more cameras 1504. In some non-limiting embodiments, the display system 1502 and/or one or more front-facing cameras 1504a may be provided at a front side of the device 1500, e.g., as indicated in FIG. 15. Additionally, or alternatively, one or more rear-facing cameras 1504b may be provided at a rear side of the device 1500. In some embodiments comprising multiple cameras 1504, some or all of the cameras may be the same as, or similar to, each other. Additionally, or alternatively, some or all of the cameras may be different from each other. In various embodiments, the location(s) and/or arrangement(s) of the camera(s) 1504 may be different than those indicated in FIG. 15. In various embodiments, cameras 1504 include lens(es) 1505. Image sensors (e.g., image sensor 1300) may receive light that passes through lens(es) 1505 to reach the image sensors.

Among other things, the device 1500 may include memory 1506 (e.g., comprising an operating system 1508 and/or application(s)/program instructions 1510), one or more processors and/or controllers 1512 (e.g., comprising CPU(s), memory controller(s), display controller(s), and/or camera controller(s), etc.), and/or one or more sensors 1516 (e.g., orientation sensor(s), proximity sensor(s), and/or position sensor(s), etc.). In some embodiments, the device 1500 may communicate with one or more other devices and/or services, such as computing device(s) 1518, cloud service(s) 1520, etc., via one or more networks 1522. For example, the device 1500 may include a network interface that enables the device 1500 to transmit data to, and receive data from, the network(s) 1522. Additionally, or alternatively, the device 1500 may be capable of communicating with other devices via wireless communication using any of a variety of communications standards, protocols, and/or technologies.

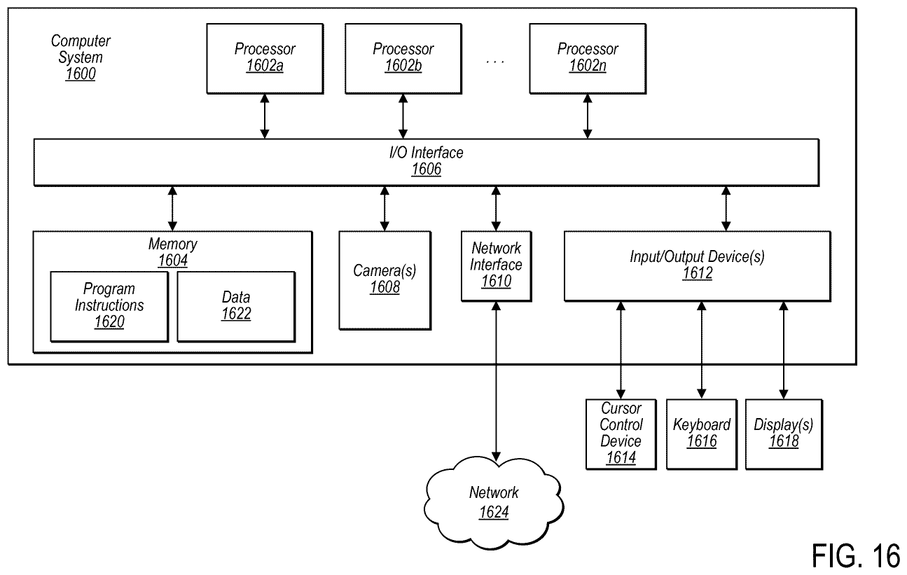

FIG. 16 illustrates a schematic block diagram of an example computing device, referred to as computer system 1600, that may include or host embodiments of an image capturing device (e.g., a camera) having an image sensor, according to some embodiments. In addition, computer system 1600 may implement methods for controlling operations of the camera and/or for performing image processing images captured with the camera. In some embodiments, the device (described herein with reference to FIG. 16) may additionally, or alternatively, include some or all of the functional components of the computer system 1600 described herein.

The computer system 1600 may be configured to execute any or all of the embodiments described above. In different embodiments, computer system 1600 may be any of various types of devices, including, but not limited to, a personal computer system, desktop computer, laptop, notebook, tablet, slate, pad, or netbook computer, mainframe computer system, handheld computer, workstation, network computer, a camera, a set top box, a mobile device, an augmented reality (AR) and/or virtual reality (VR) headset, a consumer device, video game console, handheld video game device, application server, storage device, a television, a video recording device, a peripheral device such as a switch, modem, router, or in general any type of computing or electronic device.

In the illustrated embodiment, computer system 1600 includes one or more processors 1602 coupled to a system memory 1604 via an input/output (I/O) interface 1606. Computer system 1600 further includes one or more cameras 1608 coupled to the I/O interface 1606. Computer system 1600 further includes a network interface 1610 coupled to I/O interface 1606, and one or more input/output devices 1612, such as cursor control device 1614, keyboard 1616, and display(s) 1618. In some cases, it is contemplated that embodiments may be implemented using a single instance of computer system 1600, while in other embodiments multiple such systems, or multiple nodes making up computer system 1600, may be configured to host different portions or instances of embodiments. For example, in one embodiment some elements may be implemented via one or more nodes of computer system 1600 that are distinct from those nodes implementing other elements.

In various embodiments, computer system 1600 may be a uniprocessor system including one processor 1602, or a multiprocessor system including several processors 1602 (e.g., two, four, eight, or another suitable number). Processors 1602 may be any suitable processor capable of executing instructions. For example, in various embodiments processors 1602 may be general-purpose or embedded processors implementing any of a variety of instruction set architectures (ISAs), such as the x86, PowerPC, SPARC, or MIPS ISAs, or any other suitable ISA. Also, in some embodiments, one or more of processors 1602 may include additional types of processors, such as graphics processing units (GPUs), application specific integrated circuits (ASICs), etc. In multiprocessor systems, each of processors 1602 may commonly, but not necessarily, implement the same ISA. In some embodiments, computer system 1600 may be implemented as a system on a chip (SoC). For example, in some embodiments, processors 1602, memory 1604, I/O interface 1606 (e.g. a fabric), etc. may be implemented in a single SoC comprising multiple components integrated into a single chip. For example, an SoC may include multiple CPU cores, a multi-core GPU, a multi-core neural engine, cache, one or more memories, etc. integrated into a single chip. In some embodiments, an SoC embodiment may implement a reduced instruction set computing (RISC) architecture, or any other suitable architecture.

System memory 1604 may be configured to store program instructions 1620 accessible by processor 1602. In various embodiments, system memory 1604 may be implemented using any suitable memory technology, such as static random access memory (SRAM), synchronous dynamic RAM (SDRAM), nonvolatile/Flash-type memory, or any other type of memory. Additionally, existing camera control data 1622 of memory 1604 may include any of the information or data structures to implement the techniques described above. In some embodiments, program instructions 1620 and/or data 1622 may be received, sent or stored upon different types of computer-accessible media or on similar media separate from system memory 1604 or computer system 1600. In various embodiments, some or all of the functionality described herein may be implemented via such a computer system 1600.

In one embodiment, I/O interface 1606 may be configured to coordinate I/O traffic between processor 1602, system memory 1604, and any peripheral devices in the device, including network interface 1610 or other peripheral interfaces, such as input/output devices 1612. In some embodiments, I/O interface 1606 may perform any necessary protocol, timing or other data transformations to convert data signals from one component (e.g., system memory 1604) into a format suitable for use by another component (e.g., processor 1602). In some embodiments, I/O interface 1606 may include support for devices attached through various types of peripheral buses, such as a variant of the Peripheral Component Interconnect (PCI) bus standard or the Universal Serial Bus (USB) standard, for example. In some embodiments, the function of I/O interface 1606 may be split into two or more separate components, such as a north bridge and a south bridge, for example. Also, in some embodiments some or all of the functionality of I/O interface 1606, such as an interface to system memory 1604, may be incorporated directly into processor 1602.

Network interface 1610 may be configured to allow data to be exchanged between computer system 1600 and other devices attached to a network 1624 (e.g., carrier or agent devices) or between nodes of computer system 1600. Network 1624 may in various embodiments include one or more networks including but not limited to Local Area Networks (LANs) (e.g., an Ethernet or corporate network), Wide Area Networks (WANs) (e.g., the Internet), wireless data networks, some other electronic data network, or some combination thereof. In various embodiments, network interface 1610 may support communication via wired or wireless general data networks, such as any suitable type of Ethernet network, for example; via telecommunications/telephony networks such as analog voice networks or digital fiber communications networks; via storage area networks such as Fibre Channel SANs, or via any other suitable type of network and/or protocol.

Input/output devices 1612 may, in some embodiments, include one or more display terminals, keyboards, keypads, touchpads, scanning devices, voice or optical recognition devices, or any other devices suitable for entering or accessing data by one or more computer systems 1600. Multiple input/output devices 1612 may be present in computer system 1600 or may be distributed on various nodes of computer system 1600. In some embodiments, similar input/output devices may be separate from computer system 1600 and may interact with one or more nodes of computer system 1600 through a wired or wireless connection, such as over network interface 1610.

Those skilled in the art will appreciate that computer system 1600 is merely illustrative and is not intended to limit the scope of embodiments. In particular, the computer system and devices may include any combination of hardware or software that can perform the indicated functions, including computers, network devices, Internet appliances, PDAs, wireless phones, pagers, etc. Computer system 1600 may also be connected to other devices that are not illustrated, or instead may operate as a stand-alone system. In addition, the functionality provided by the illustrated components may in some embodiments be combined in fewer components or distributed in additional components. Similarly, in some embodiments, the functionality of some of the illustrated components may not be provided and/or other additional functionality may be available.

Those skilled in the art will also appreciate that, while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computer system 1600 may be transmitted to computer system 1600 via transmission media or signals such as electrical, electromagnetic, or digital signals, conveyed via a communication medium such as a network and/or a wireless link. Various embodiments may further include receiving, sending or storing instructions and/or data implemented in accordance with the foregoing description upon a computer-accessible medium. Generally speaking, a computer-accessible medium may include a non-transitory, computer-readable storage medium or memory medium such as magnetic or optical media, e.g., disk or DVD/CD-ROM, volatile or non-volatile media such as RAM (e.g. SDRAM, DDR, RDRAM, SRAM, etc.), ROM, etc. In some embodiments, a computer-accessible medium may include transmission media or signals such as electrical, electromagnetic, or digital signals, conveyed via a communication medium such as network and/or a wireless link.

The methods described herein may be implemented in software, hardware, or a combination thereof, in different embodiments. In addition, the order of the blocks of the methods may be changed, and various elements may be added, reordered, combined, omitted, modified, etc. Various modifications and changes may be made as would be obvious to a person skilled in the art having the benefit of this disclosure. The various embodiments described herein are meant to be illustrative and not limiting. Many variations, modifications, additions, and improvements are possible. Accordingly, plural instances may be provided for components described herein as a single instance. Boundaries between various components, operations and data stores are somewhat arbitrary, and particular operations are illustrated in the context of specific illustrative configurations. Other allocations of functionality are envisioned and may fall within the scope of claims that follow. Finally, structures and functionality presented as discrete components in the example configurations may be implemented as a combined structure or component. These and other variations, modifications, additions, and improvements may fall within the scope of embodiments as defined in the claims that follow.

1. A pixel array device, comprising:
a silicon substrate;
an array of pixel structures arranged in the substrate, the array being configured to generate signals based on photoelectrons accumulated by the pixels when exposed to light, wherein the pixel structures are square-shaped pixel structures having photodiodes formed in the substrate, the square-shaped pixel structures including:
a first set of pixel structures of a first type, wherein the first type of pixel structures include one photodiode formed in the substrate per square-shaped pixel structure; and
a second set of pixel structures of a second type, wherein the second type of pixel structures include two photodiodes formed in the substrate per square-shaped pixel structure;
a first signal output circuit coupled to the first set of pixel structures, wherein the first signal output circuit is configured to receive readout signals from the one photodiodes in the first set of pixel structures; and
a second signal output circuit coupled to the second set of pixel structures, wherein the second signal output circuit is configured to receive readout signals from the two photodiodes in the second set of pixel structures.

2. The pixel array device of claim 1, wherein the first type of pixel structures are square photodiode pixel structures.

3. The pixel array device of claim 1, wherein the second type of pixel structures are split photodiode pixel structures.

4. The pixel array device of claim 1, further comprising:
a first analog-to-digital converter (ADC) circuit coupled to the first signal output circuit; and
a second ADC circuit coupled to the second signal output circuit.

5. The pixel array device of claim 4, wherein the first ADC circuit and the second ADC circuit are configured to receive the readout signals from the first signal output circuit and the second signal output circuit, respectively, in parallel.

6. The pixel array device of claim 1, further comprising:
a first row addressing circuit coupled to inputs of the one photodiodes in the first set of pixel structures; and
a second row addressing circuit coupled to inputs of the two photodiodes in the second set of pixel structures.

7. The pixel array device of claim 1, wherein the array includes the first set of pixel structures and the second set of pixel structures arranged in a repeating regular pattern.

8. The pixel array device of claim 1, wherein the array is a color filter array, and wherein the first type of pixel structures are configured to accumulate photoelectrons when exposed to green light, and wherein the second type of pixel structures are configured to accumulate photoelectrons when exposed to blue light or red light.

9. The pixel array device of claim 1, further comprising micro-lens structures positioned over the pixel structures with one micro-lens structure per pixel structure.

10. The pixel array device of claim 1, further comprising optical shields positioned in at least some of the first set of pixel structures, wherein an optical shield is positioned in half of a corresponding pixel structure.

11. The pixel array device of claim 10, wherein some of the optical shields are positioned in left halves of the corresponding pixel structures and some of the optical shields are positioned in right halves of the corresponding pixel structures.

12. An image sensor device, comprising:
a silicon substrate;
a plurality of square-shaped pixel structures formed in the substrate, the pixel structures being configured to generate signals based on photoelectrons accumulated by the pixel structures when exposed to light, wherein the pixel structures include:
a set of square photodiode pixel structures having one photodiode formed in the substrate per square-shaped pixel structure; and
a set of split photodiode pixel structures having two photodiodes formed in the substrate per square-shaped pixel structure;
a first row addressing circuit coupled to the set of square photodiode pixel structures, wherein the first row addressing circuit is configured to provide a first control signal to the one photodiode in the set of square photodiode pixel structures;
a second row addressing circuit coupled to the set of split photodiode pixel structures, wherein the second row addressing circuit is configured to provide a second control signal to the two photodiodes in the set of split photodiode pixel structures; and
an image signal processing circuit coupled to signal outputs of the set of square photodiode pixel structures and signal outputs of the set of split photodiode pixel structures, wherein the image signal processing circuit is configured to generate digital images based on a combination of output signals from the set of square photodiode pixel structures and output signals from the set of split photodiode pixel structures.

13. The image sensor device of claim 12, further comprising:
a first analog-to-digital converter (ADC) circuit coupled to the signal outputs of the set of square photodiode pixel structures, the first ADC circuit being configured to generate a first digital signal output corresponding to analog signal outputs from the set of square photodiode pixel structures; and
a second ADC circuit coupled to the signal outputs of the set of split photodiode pixel structures, the second ADC circuit being configured to generate a second digital signal output corresponding to analog signal outputs from the set of split photodiode pixel structures.

14. The image sensor device of claim 13, wherein the image signal processing circuit is configured to generate digital images based on a combination of the first digital signal output and the second digital signal output.

15. The image sensor device of claim 12, wherein the set of square photodiode pixel structures and the set of split photodiode pixel structures are arranged in an alternating regular pattern of pixel structures in the substrate.

16. A system, comprising:
a camera, comprising:
one or more lenses; and
an image sensor configured to receive light that has passed through the lenses to reach the image sensor, comprising:
a plurality of square-shaped pixel structures formed in a substrate, the pixel structures being configured to generate signals based on photoelectrons accumulated by the pixel structures when exposed to light, wherein the pixel structures include:
a set of square photodiode pixel structures having one photodiode formed in the substrate per pixel structure; and
a set of split photodiode pixel structures having two photodiodes formed in the substrate per square-shaped pixel structure; and
a first signal output circuit coupled to the set of square photodiode pixel structures, wherein the first signal output circuit is configured to receive readout signals from the one photodiodes in the set of square photodiode pixel structures;
a second signal output circuit coupled to the set of split photodiode pixel structures, wherein the second signal output circuit is configured to receive readout signals from the two photodiodes in the set of split photodiode pixel structures; and
an image signal processor configured to process the readout signals from the first signal output circuit and the second signal output circuit to generate one or more images.

17. The system of claim 16, wherein the set of square photodiode pixel structures are configured to generate readout signals when exposed to green light, and wherein the set of split photodiode pixel structures are configured to generate readout signals when exposed to blue light or red light.

18. The system of claim 16, wherein the first signal output circuit is configured to output a first signal to the image signal processor and the second signal output circuit is configured to output a second signal to the image signal processor, the image signal processor being configured to generate the one or more images by processing both the first signal and the second signal.

19. The system of claim 18, wherein the first signal output circuit is configured to output the first signal synchronously with the second signal output by the second signal output circuit.

20. The system of claim 16, further comprising:
a first row addressing circuit coupled to inputs of the one photodiodes in the set of square photodiode pixel structures; and
a second row addressing circuit coupled to inputs of the two photodiodes in the set of split photodiode pixel structures.
